(19) United States
(12) Patent Application Publication
(10) Pub. No.: US 2026/0090239 A1
(43) Pub. Date: Mar. 26, 2026

(54) DISPLAY DEVICE INCLUDING TAPE AND ELECTRONIC DEVICE INCLUDING THE SAME

(71) Applicant: SAMSUNG DISPLAY CO., LTD., YONGIN-SI (KR)

(72) Inventor: HYUNSEOP SONG, Yongin-si (KR)

(21) Appl. No.: 19/320,716

(22) Filed: Sep. 5, 2025

(30) Foreign Application Priority Data
Sep. 23, 2024 (KR) 10-2024-0127884

(51) Int. Cl. H10K 59/80; H05K 1/02; H05K 1/18; H10K 59/131

(52) U.S. Cl. CPC H10K 59/8722; H05K 1/028; H05K 1/189; H10K 59/131; H05K 2201/10128

(57) ABSTRACT

A display device includes a display panel. The display panel includes a display area including a plurality of pixels, and a peripheral area proximate to the display area. The peripheral area includes a pad area spaced apart from a side of the display area in a first direction. The display device includes a printed circuit board electrically connected to the display panel. The printed circuit board includes at least one ground portion. The display device includes a cover covering the printed circuit board. The cover includes at least one cut-out area exposing the at least one ground portion. The display device includes a conductive tape disposed in the at least one cut-out area. The conductive tape is electrically connected to the at least one ground portion of the printed circuit board.

### CROSS-REFERENCE TO RELATED APPLICATION

This application claims priority under 35 U.S.C. § 119 to Korean Patent Application No. 10-2024-0127884, filed on Sep. 23, 2024, in the Korean Intellectual Property Office, the disclosure of which is incorporated by reference herein in its entirety.

### 1. TECHNICAL FIELD

The present disclosure relates to a display device and an electronic device. More specifically, the present disclosure relates to the display device including tape and the electronic device including the same.

### 2. DISCUSSION OF THE RELATED ART

Because of the use of high frequency data in display devices, issues such as increased static electricity generation on the components of display devices and included circuit boards have become prevalent, leading to frequent malfunctions of electronic devices. To mitigate such issues, the static electricity may be discharged by grounding.

### SUMMARY

According to embodiments of the disclosure, a display device includes a display panel. The display panel includes a display area including a plurality of pixels, and a peripheral area proximate to the display area. The peripheral area includes a pad area spaced apart from a side of the display area in a first direction. The display device includes a printed circuit board electrically connected to the display panel. The printed circuit board includes at least one ground portion. The display device includes a cover covering the printed circuit board. The cover includes at least one cut-out area exposing the at least one ground portion. The display device includes a conductive tape disposed in the at least one cut-out area. The conductive tape is electrically connected to the at least one ground portion of the printed circuit board.

In embodiments, the cover may include a first insulating layer. The cover may include a conductive layer disposed on the first insulating layer. The cover may include a second insulating layer disposed on the conductive layer.

In embodiments, the conductive tape may include a discharge layer including a conductive material. The conductive tape may include a cover layer disposed on the discharge layer. The cover layer may include an insulating material.

In embodiments, the discharge layer may include a same material as the conductive layer of the cover. The cover layer may include a same material as the first insulating layer. The cover layer may include a same material as the second insulating layer of the cover.

In embodiments, the discharge layer and the conductive layer may both include aluminum.

In embodiments, a cover panel may be disposed under the display panel. The cover panel may include a conductive material.

In embodiments, the discharge layer of the conductive tape may be electrically connected to the cover panel and the at least one ground portion.

In embodiments, the conductive tape may be spaced apart from the cover.

In embodiments, the at least one cut-out area of the cover may correspond one-to-one with the at least one ground portion.

In embodiments, the conductive tape may correspond one-to-one with the at least one ground portion and the at least one cut-out area.

In embodiments, a driver chip may be disposed on the pad area of the display panel. The driver chip may be configured to provide driving signals to the plurality of pixels.

In embodiments, a connection circuit board may be disposed on the pad area of the display panel. The connection circuit board may be connected to the display panel and the printed circuit board.

In embodiments, the connection circuit board may be bent around a bending axis extending parallel to a second direction. The second direction may intersect the first direction.

In embodiments, the cover may include an insulating material. The cover may be single-layered.

According to embodiments of the disclosure, a display device includes a display panel. The display panel includes a display area including a plurality of pixels, and a peripheral area including a pad area proximate to the display area. The pad area is spaced apart from a side of the display area in a first direction. A display device includes a cover panel disposed under the display panel. The cover panel includes a conductive material. A display device includes a printed circuit board electrically connected to the display panel. The printed circuit board includes at least one ground portion. A display device includes a cover covering the printed circuit board. The cover is electrically connected to the at least one ground portion. A display device includes an adhesive tape attached to the cover and to the cover panel. At least a portion of the adhesive tape overlaps the at least one ground portion of the printed circuit board.

In embodiments, the cover may include a first insulating layer. A conductive layer may be disposed on the first insulating layer. A second insulating layer may be disposed on the conductive layer.

In embodiments, a ground area may be defined in the cover by removing a portion of the first insulating layer to expose one surface of the conductive layer.

In embodiments, the ground area of the cover may correspond one-to-one with the at least one ground portion. The adhesive tape may correspond one-to-one with the at least one ground portion and to the ground area.

In embodiments, a connection circuit board may be disposed on the peripheral area of the display panel. The connection circuit board may be bent around a bending axis extending parallel to a second direction. The second direction may intersect the first direction.

According to embodiments of the disclosure, an electronic device includes a display device and a processor configured to drive the display device. The display device includes a display panel. The display panel includes a display area including a plurality of pixels, and a peripheral area proximate to the display area, the peripheral area including a pad area spaced apart from a side of the display area in a first direction. The display device includes a printed circuit board electrically connected to the display panel. The printed circuit board includes at least one ground portion. The display device includes a cover covering the printed circuit board. The cover includes at least one cut-out area exposing the at least one ground portion. The display device includes a conductive tape disposed in the at least one cut-out area. The conductive tape is electrically connected to the at least one ground portion of the printed circuit board.

### BRIEF DESCRIPTION OF THE DRAWINGS

The above and other features of the disclosure will become more apparent from the following description of the embodiments, taken in conjunction with the accompanying drawings, in which:

FIG. 1 is a perspective view illustrating a display device according to an embodiment of the present disclosure.

FIG. 2 is a perspective view illustrating the display panel and the cover of the display device shown in FIG. 1.

FIG. 3 is a cross-sectional view illustrating an embodiment cut along the line I-I′ of the display device shown in FIG. 2.

FIG. 4 is a cross-sectional view illustrating an embodiment of the cover shown in FIG. 3.

FIG. 5 is a perspective view illustrating an embodiment in which the cover of the display device shown in FIG. 2 is separated.

FIG. 6 is a perspective view illustrating an embodiment in which the connection circuit board of the display device shown in FIG. 5 is in an unfolded state.

FIG. 7 is a perspective view illustrating an embodiment of a rear side of the display device shown in FIG. 2.

FIG. 8 is a cross-sectional view illustrating an embodiment of the conductive tape shown in FIG. 7.

FIG. 9 is a perspective view illustrating an embodiment in which the cover of the display device shown in FIG. 7 is separated.

FIG. 10 is a perspective view illustrating an embodiment in which the connection circuit board of the display device shown in FIG. 9 is in an unfolded state.

FIG. 11 is a cross-sectional view illustrating an embodiment of the circuit board shown in FIG. 3.

FIG. 12 is a cross-sectional view illustrating an embodiment cut along the line II-II′ shown in FIG. 9.

FIG. 13 is a cross-sectional view illustrating an embodiment of the display panel shown in FIG. 3.

FIGS. 14, 15, 16, 17, 18, 19, and 20 are plan views illustrating a manufacturing method of the display device shown in FIG. 2.

FIG. 21 is a perspective view illustrating an embodiment of a rear side of the display device shown in FIG. 2.

FIG. 22 is a perspective view illustrating an embodiment in which the cover of the display device shown in FIG. 21 is separated.

FIG. 23 is a perspective view illustrating an embodiment in which the connection circuit board of the display device shown in FIG. 22 is in an unfolded state.

FIG. 24 is a perspective view illustrating an embodiment of a rear side of the display device shown in FIG. 2.

FIG. 25 is a plan view illustrating an embodiment of the ground portion of the cover shown in FIG. 22.

FIG. 26 is a cross-sectional view illustrating an embodiment cut along the line III-III′ of FIG. 25.

FIG. 27 is a cross-sectional view illustrating an embodiment in which the cover shown in FIG. 26 contacts the circuit board.

FIG. 28 is a cross-sectional view illustrating an embodiment cut along the line I-I′ of the display device shown in FIG. 2.

FIG. 29 is a block diagram illustrating an electronic device according to an embodiment of the present disclosure.

FIG. 30 is a schematic diagram illustrating various embodiments of the electronic device shown in FIG. 29.

### DETAILED DESCRIPTION

The present invention will now be described more fully hereinafter with reference to the accompanying drawings, in which preferred embodiments of the invention are shown. In the following description, portions necessary for understanding an operation according to the disclosure may be described, and descriptions of other portions may be omitted. In addition, the disclosure may be embodied in other forms without being necessarily limited to the embodiments described herein. The embodiments described herein are provided so that this disclosure will be thorough and complete, and will fully convey the scope of the invention to those skilled in the art.

Although the terms “first”, “second”, etc. may be used herein to describe various elements, these elements, should not necessarily be limited by these terms. These terms may be used to distinguish one element from another element. Thus, a first element discussed below may be termed a second element without departing from the teachings of one or more embodiments. The description of an element as a “first” element may not require or imply the presence of a second element or other elements. The terms “first”, “second”, etc., may also be used herein to differentiate different categories or sets of elements. For conciseness, the terms “first”, “second”, etc., may represent “first-category (or first-set)”, “second-category (or second-set)”, etc., respectively.

Embodiments of the present disclosure are described with the understanding that when an element is referred to as being “connected” or “coupled” to another element, it may be directly connected or coupled to the other element or intervening element(s) may be present. In contrast, when an element is referred to as being “directly connected” or “directly coupled” to another element, there might be no intervening elements present. Other words used to describe the relationship between elements should be interpreted in a like fashion (e.g., “between” versus “directly between,” “adjacent” versus “directly adjacent,” etc.).

The terminology used herein is for the purpose of describing example embodiments only and is not necessarily intended to be limiting of the present inventive concept. As used herein, the singular forms “a,” “an,” and “the” may be intended to include plural forms as well, unless the context clearly indicates otherwise. Embodiments of the present disclosure are described with the understanding that the terms “comprises” and/or “comprising”, when used herein, specify the presence of stated features, integers, steps, operations, elements, and/or components, but do not necessarily preclude the presence or addition of one or more other features, integers, steps, operations, elements, components, and/or groups thereof.

Spatially relative terms such as “below”, “at the bottom”, “lower”, “below”, “above”, “on top”, “on the top”, “on”, etc., are used to explain a relationship between components shown in the drawings. The terms are relative concepts and are explained based on the direction indicated in the drawings. Spatially relative terms are intended to include other directions in use, in operation, and/or in manufacturing, in addition to the direction depicted in the drawings. For example, in case that a device shown in the drawing is turned upside down, elements depicted as being positioned “under” other elements or features are positioned in a direction “on” the other elements or features. Therefore, in an embodiment, the term “under” may include both directions of “on” and “under”.

Hereinafter, embodiments will be described in detail with reference to the accompanying drawings. Same reference numerals are used for the same components in the drawings, and redundant descriptions of the same components may be omitted. To the extent that an element is not described in detail with respect to a figure, it may be understood that the element is at least similar to a corresponding element that has been described elsewhere within the present disclosure.

In the present disclosure, a plane may be defined by a first direction D1 and a second direction D2 that intersects the first direction D1. For example, the second direction D2 may be perpendicular to the first direction D1. In addition, a third direction D3 may be a direction normal to the plane. For example, the third direction D3 may be perpendicular to the plane formed by the first direction D1 and the second direction D2.

Traditionally, a display device includes a circuit board and a cover. However, the generation of static electricity on the circuit board and other components of the electric device may cause the electric device to malfunction. Moreover, during manufacturing, the cover of the electric device may detach due to thermal expansion, thus making it challenging to discharge the static electricity by grounding.

To resolve these challenges, in embodiments, one or more cut-out areas may be defined in a cover of an electronic device, exposing a ground portion of a circuit board. A conductive tape may be connected to the ground portion to ensure the discharging of the electric charge. Since, in an embodiment, the ground portion of the circuit board may be connected to a conductive tape, the effects of expansion and shrinkage of a cover may also be minimized.

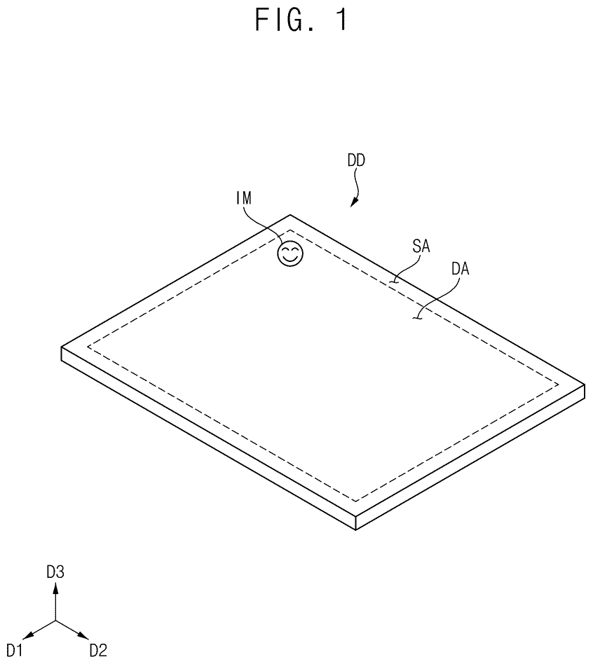

FIG. 1 is a perspective view showing a display device according to an embodiment of the present disclosure.

Referring to FIG. 1, the display device DD may include a display area DA and a peripheral area SA. The display area DA may be at least partially surrounded by the peripheral area SA. In an embodiment, the peripheral area may be proximate to the display area.

The display area DA may be an area capable of generating light or adjusting a transmittance of light provided by an external light source to display images. The peripheral area SA may be an area that does not display images. However, embodiments of the present disclosure are not necessarily limited thereto, and at least a portion of the peripheral area SA may display images.

The display area DA may display a plurality of images IM. Through the plurality of images IM, users may receive information from the display device DD.

Although the display device DD is shown as having a rectangular shape in a plan view, the embodiments of the present disclosure are not necessarily limited thereto. The display device DD may include foldable displays, rollable displays, etc. For example, the displays may be bent, folded, or rolled to a noticeable extent without cracking or otherwise sustaining damage.

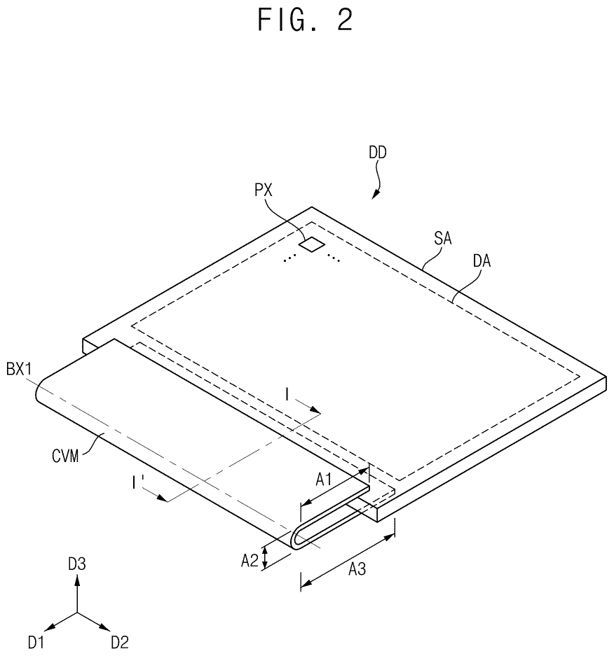

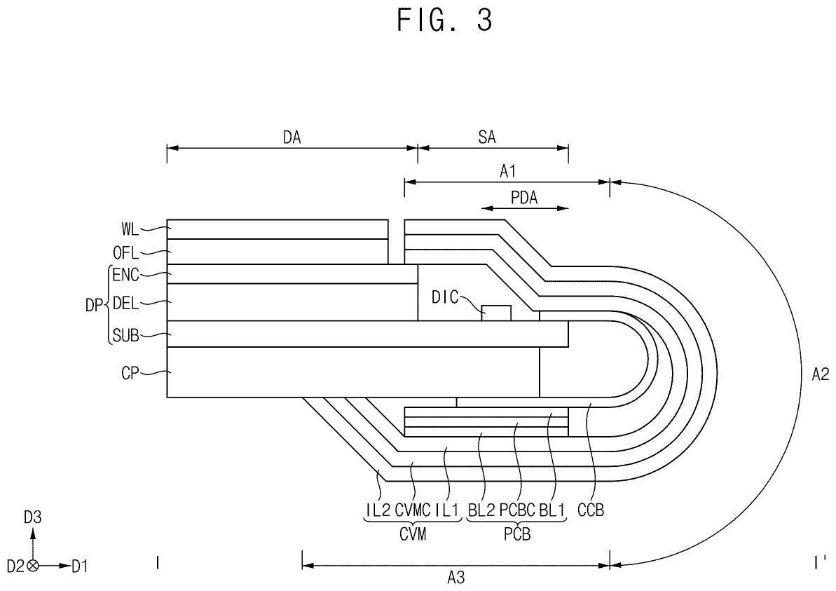

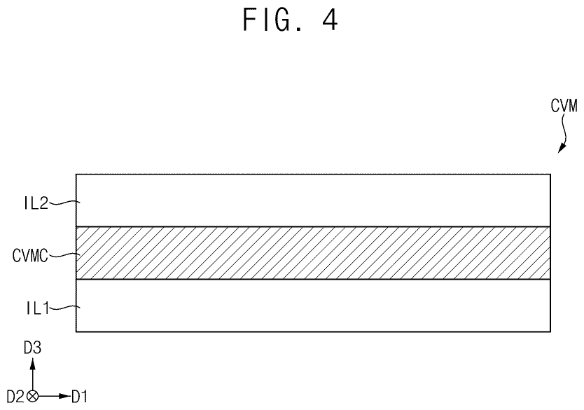

FIG. 2 is a perspective view showing the display panel and the cover of the display device shown in FIG. 1. FIG. 3 is a cross-sectional view showing an embodiment cut along the line I-I′ of the display device shown in FIG. 2. FIG. 4 is a cross-sectional view illustrating an embodiment of the cover shown in FIG. 3.

Referring to FIGS. 1, 2, and 3, the display device DD may include a cover panel CP, a display panel DP, an optical function layer OFL, a window layer WL, a driver chip DIC, a connection circuit board CCB, a circuit board PCB, and a cover CVM. The display panel DP may include a substrate SUB, a display element layer DEL, and an encapsulation layer ENC. In an embodiment, the circuit board PCB may be a printed circuit board.

The cover panel CP may be disposed below the display panel DP. The cover panel CP may protect the display panel DP from external impacts or ingress of foreign substances. The cover panel CP may have a multilayer structure. For example, the cover panel CP may include a support layer disposed at the bottom, a heat dissipation layer performing a heat dissipation function, and a cushion layer for absorbing impacts.

In an embodiment, the cover panel CP may include conductive materials. For example, the support layer may include metal as a conductive material, supporting the cover panel CP. By including metal, the cover panel CP may perform a discharge function for the display device DD. For example, static electricity generated in components such as the circuit board PCB may be discharged through the cover panel CP, thereby protecting the display device DD.

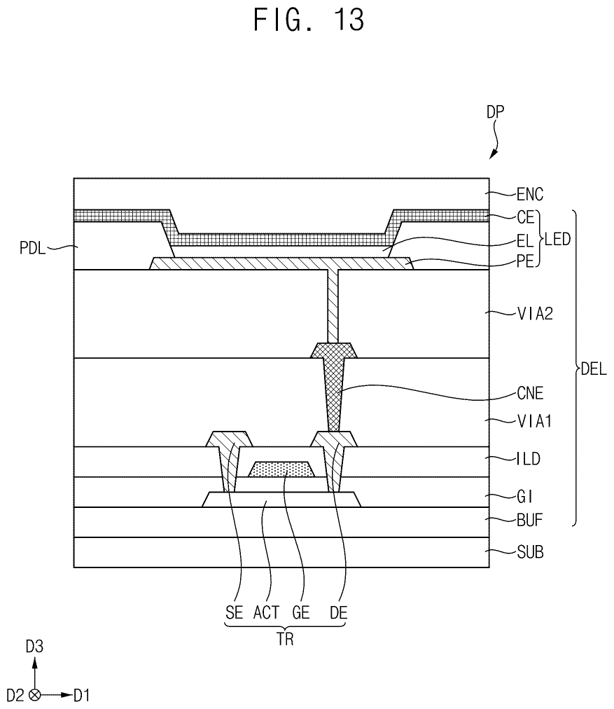

The display panel DP may provide visual information to the user of the display device DD, according to electrical signals transmitted from the driver chip DIC. For example, the display panel DP may emit light combining red, green, and/or blue light through a plurality of pixels PX to provide visual information to the users. The display panel DP will be further described with reference to FIG. 13.

The optical function layer OFL may be disposed on the display panel DP. For example, the optical function layer OFL may be a layer that performs optical functions by adjusting light.

In an embodiment, the optical function layer OFL may be a polarizing layer. For example, the optical function layer OFL may polarize light incident on to the display panel DP from an external source. The optical function layer OFL may be stretched in one direction. A stretching direction of the optical function layer OFL may serve as an absorption axis, and a direction perpendicular to the stretching direction may serve as a transmission axis. However, the optical function layer OFL, according to the embodiments of the present disclosure, is not necessarily limited thereto and may include a color filter instead of a polarizing layer. For example, the display device DD may have a structure that might not include a polarizing layer.

The window layer WL may be disposed on the optical function layer OFL. In an embodiment, the window layer WL may be ultrathin glass (UTG). For example, the window layer WL may include soda-lime glass, alkali aluminosilicate glass, borosilicate glass, or lithium aluminosilicate glass, which may be used alone or in combination. However, the window layer WL of the present disclosure is not necessarily limited thereto and may include various materials such as plastic.

The circuit board PCB may be disposed below the cover panel CP. The circuit board PCB may be electrically connected to electronic components (e.g., a timing controller). The circuit board PCB may generate scan control signals, data control signals, and image data using video signals and multiple timing signals received from the electronic components. The generated scan control signals, data control signals, and image data may be provided to the driver chip DIC through the circuit board PCB.

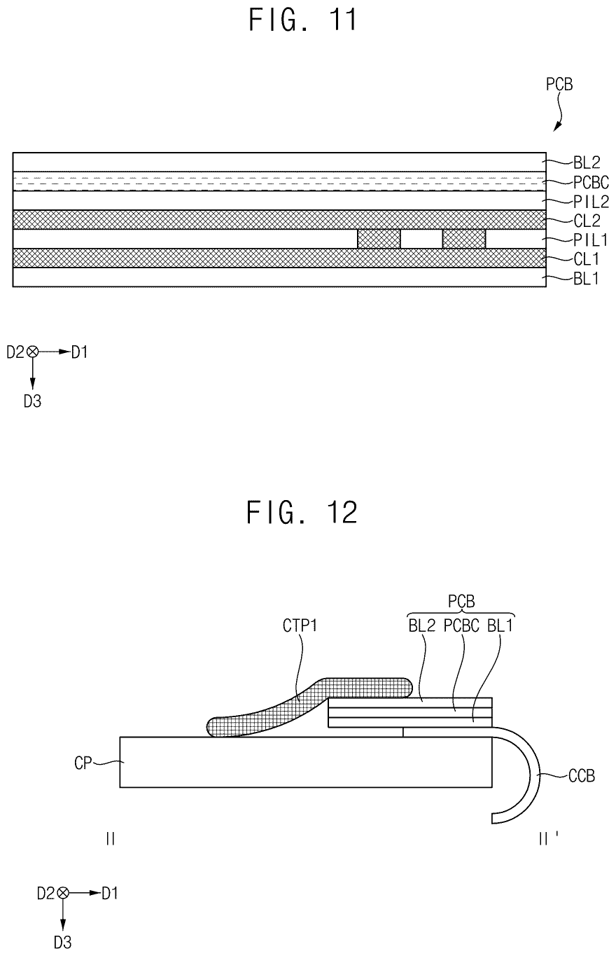

In an embodiment, the circuit board PCB may include three layers. The circuit board PCB may include a first base layer BL1, a conductive pattern PCBC, and a second base layer BL2. For example, each of the first base layer BL1 and the second base layer BL2 may include insulating materials. The conductive pattern PCBC may include metallic materials for discharging. The cross-sectional structure of the circuit board PCB will be further described with reference to FIG. 11.

The driver chip DIC may be disposed on the substrate SUB of the display device DD. For example, the driver chip DIC of the display device DD may have a chip-on-glass (COG) or chip-on-plastic (COP) structure disposed on the substrate SUB. However, embodiments of the present disclosure are not necessarily limited thereto. The driver chip DIC may also be disposed on the connection circuit board CCB. For example, the display device DD may have a chip-on-film (COF) structure.

The connection circuit board CCB may be attached to one side of the substrate SUB. For example, as shown in FIG. 3, the connection circuit board CCB may be attached to the pad area PDA of the substrate SUB. For example, one end of the connection circuit board CCB may be attached to the pad area PDA of the substrate SUB, and the other end located opposite the one end of the connection circuit board CCB may be attached to the circuit board PCB. The connection circuit board CCB may electrically connect the driver chip DIC and the circuit board PCB. For example, driving signals transmitted from the circuit board PCB may be delivered to the driver chip DIC through the connection circuit board CCB.

Referring further to FIGS. 3 and 4, the cover CVM may cover the circuit board PCB and the driver chip DIC. In an embodiment, one end of the cover CVM may be attached to the encapsulation layer ENC of the display panel DP, and an opposite end of the cover may be attached to the cover panel CP. For example, the cover CVM may protect the circuit board PCB and the driver chip DIC from external impacts or ingress of foreign substances.

In an embodiment, the cover CVM may include three layers. For example, the cover CVM may include a first insulating layer IL1, a conductive layer CVMC, and a second insulating layer IL2. The conductive layer CVMC may be disposed on the first insulating layer IL1, and the second insulating layer IL2 may be disposed on the conductive layer CVMC. For example, the first insulating layer IL1 may be attached to the second base layer BL2 of the circuit board PCB. However, embodiments of the present disclosure are not necessarily limited thereto. In other embodiments, the cover CVM may have a single-layer structure including one insulating layer.

For example, the first insulating layer IL1 and the second insulating layer IL2 may include insulating materials such as polyimide (Pl) or polyethylene terephthalate (PET).

The conductive layer CVMC may include aluminum (Al), gold (Au), silver (Ag), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys including aluminum, alloys including silver, alloys including copper, or alloys including molybdenum. These may be used alone or in combination. However, embodiments of the present disclosure are not necessarily limited thereto.

In an embodiment, as shown in FIG. 2, the cover CVM may be bent around the first bending axis BX1. The first bending axis BX1 may be an imaginary axis extending parallel to the second direction D2, intersecting with the first direction D1. For example, the cover CVM may be bent around the first bending axis BX1 extending along the second direction D2. Accordingly, the cover CVM may cover at least a portion of the upper and lower surfaces of the substrate SUB.

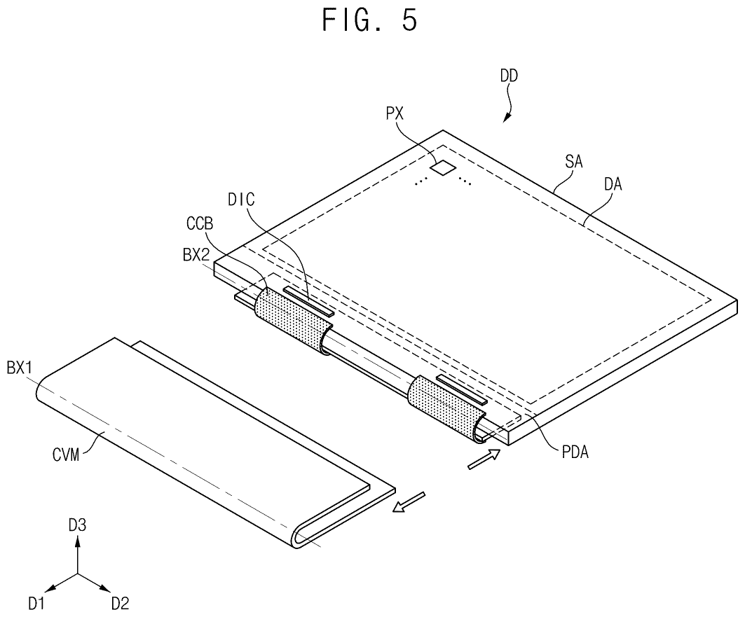

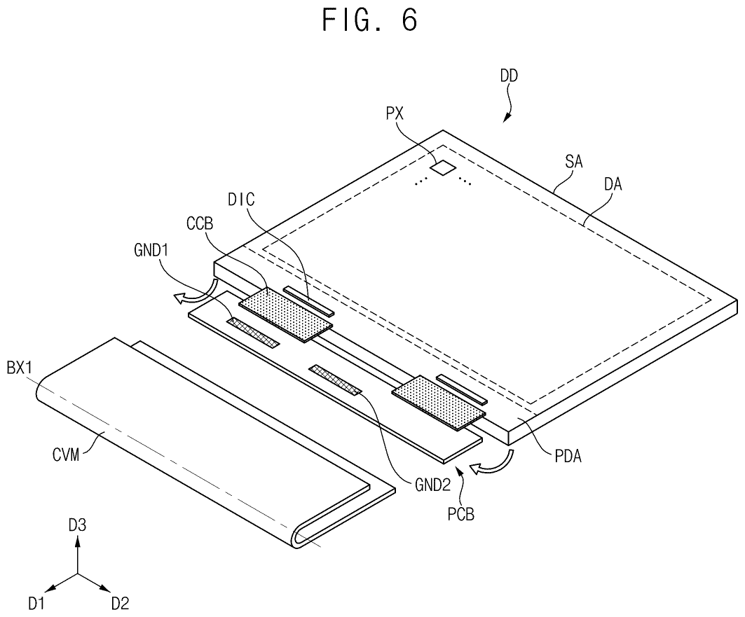

FIG. 5 is a perspective view showing an embodiment in which the cover of the display device shown in FIG. 2 is separated. FIG. 6 is a perspective view showing an embodiment in which the connection circuit board of the display device shown in FIG. 5 is in an unfolded state.

Referring to FIGS. 2, 5, and 6, the cover CVM may include a first area A1, a second area A2, and a third area A3. The first area A1 may cover at least a portion of an upper surface of the substrate SUB. The second area A2 may cover at least a portion of a side surface of the substrate SUB. The third area A3 may cover at least a portion of a lower surface of the substrate SUB.

The first area A1 of the cover CVM may be attached to one side of a peripheral area SA of the display device DD. For example, the first area A1 of the cover CVM may be attached to a pad area PDA. The pad area PDA may be spaced apart from the display area DA in the first direction D1. The pad area PDA may be an area where components such as the connection circuit board CCB may be attached.

As shown in FIG. 5, the connection circuit board CCB may be bent around a second bending axis BX2 parallel to a first bending axis BX1. When the connection circuit board CCB is bent around the second bending axis BX2, the circuit board PCB may be attached beneath the substrate SUB.

As shown in FIG. 6, when the connection circuit board CCB is in an unfolded state, an upper surface of the circuit board PCB may face a third direction D3. For example, when the connection circuit board CCB is in an unfolded state, a first ground portion GND1 and a second ground portion GND2 of the circuit board PCB may face the third direction D3.

In an embodiment, the circuit board PCB may include the first ground portion GND1 and the second ground portion GND2. The first ground portion GND1 and the second ground portion GND2 may be defined at intervals along a second direction D2. The first ground portion GND1 and the second ground portion GND2 may serve as pathways for discharging static electricity generated on the circuit board PCB.

In FIG. 6, the circuit board PCB is illustrated as including the first ground portion GND1 and the second ground portion GND2, however, the embodiments of the present disclosure are not necessarily limited thereto. For example, the circuit board PCB may include one, three, or more ground portions.

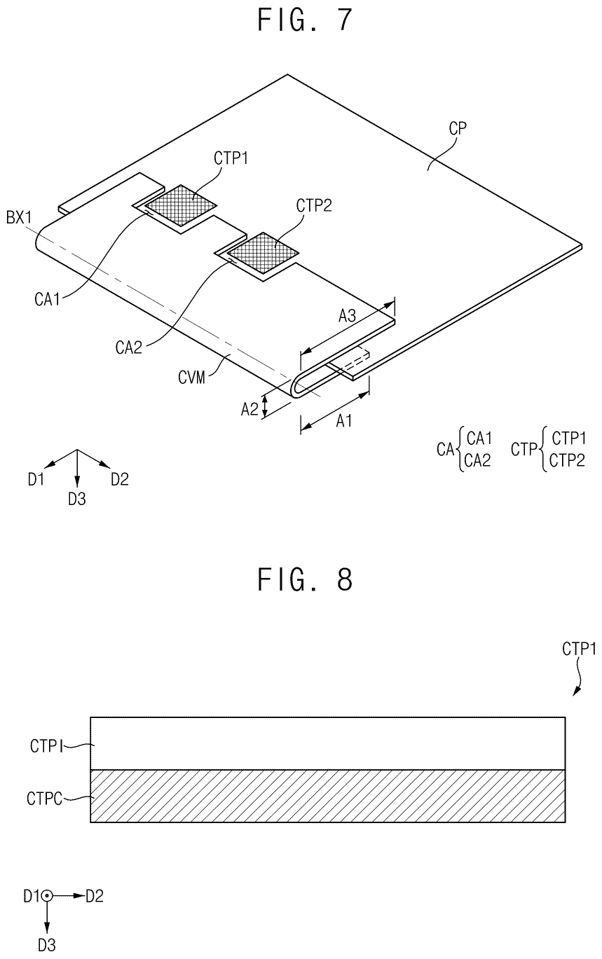

FIG. 7 is a perspective view showing an embodiment of a rear side of the display device shown in FIG. 2. FIG. 8 is a cross-sectional view showing an embodiment of the conductive tape shown in FIG. 7.

Referring to FIG. 7, a cut-out area CA may be defined in the cover CVM. The cut-out area CA may have a U-shape, extending in the first direction D1, from one end of the cover CVM. In an embodiment, the cut-out area CA may have a U-shape extending from an edge of the cover CVM, in the first direction D1.

For example, the cut-out area CA may include a first cut-out area CAL and a second cut-out area CA2. Each of the first cut-out area CAL and the second cut-out area CA2 may be defined at intervals along the second direction D2. The cut-out area CA may be defined in various shapes, such as a circular shape, an elliptical shape, or a polygonal shape, in a plan view.

The first cut-out area CAL and the second cut-out area CA2 of the cover CVM may accommodate a first conductive tape CTP1 and a second conductive tape CTP2, respectively. For example, the first conductive tape CTP1 may be disposed in the first cut-out area CA1, and the second conductive tape CTP2 may be disposed in the second cut-out area CA2. In an embodiment, the conductive tape CTP may correspond one-to-one with the cut-out area CA. In an embodiment, the cut-out area CA may correspond one-to-one with the ground portion GND.

In an embodiment, the conductive tape CTP may be spaced apart from the cover CVM, in a plan view. The first conductive tape CTP1 may be spaced apart from the cover CVM in the first cut-out area CA1, and the second conductive tape CTP2 may be spaced apart from the cover CVM in the second cut-out area CA2. However, the embodiments of the present disclosure are not necessarily limited thereto. In some embodiments, the conductive tape CTP may contact the side of the cover CVM within the cut-out area CA.

Referring further to FIG. 8, the conductive tape CTP may have two layers. For example, the conductive tape CTP may include a discharge layer CTPC and a cover layer CTP1. The cover layer CTP1 may be disposed on the discharge layer CTPC. The discharge layer CTPC may include metallic materials, while the cover layer CTP1 may include insulating materials.

The discharge layer CTPC may include a same material as the conductive layer CVMC of the cover CVM. The cover layer CTP1 may include the same materials as the first insulating layer IL1 and the second insulating layer IL2 of the cover CVM.

In an embodiment, the conductive tape CTP may be manufactured by removing a portion of the cover CVM. For example, by removing portions of the cover CVM corresponding to the first cut-out area CA1 and the second cut-out area CA2, and by removing the first insulating layer IL1 or the second insulating layer IL2 from the removed portions, the conductive tape CTP may be formed. In an embodiment, the discharge layer CTPC may include a same material as the conductive layer CVMC, and the cover layer CTP1 may include a same material as the first insulating layer IL1 and the second insulating layer IL2. However, the embodiments of the present disclosure are not necessarily limited thereto. The conductive tape CTP may be separately provided and attached to the ground portion GND, regardless of the cover CVM.

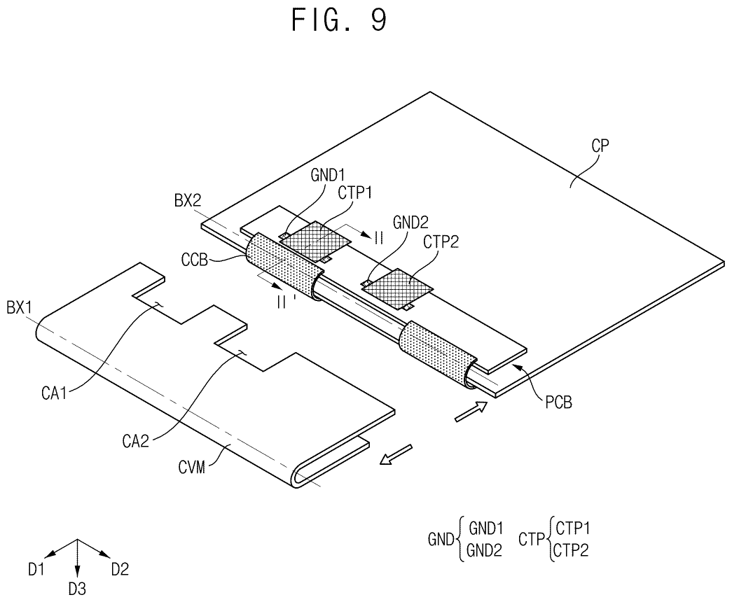

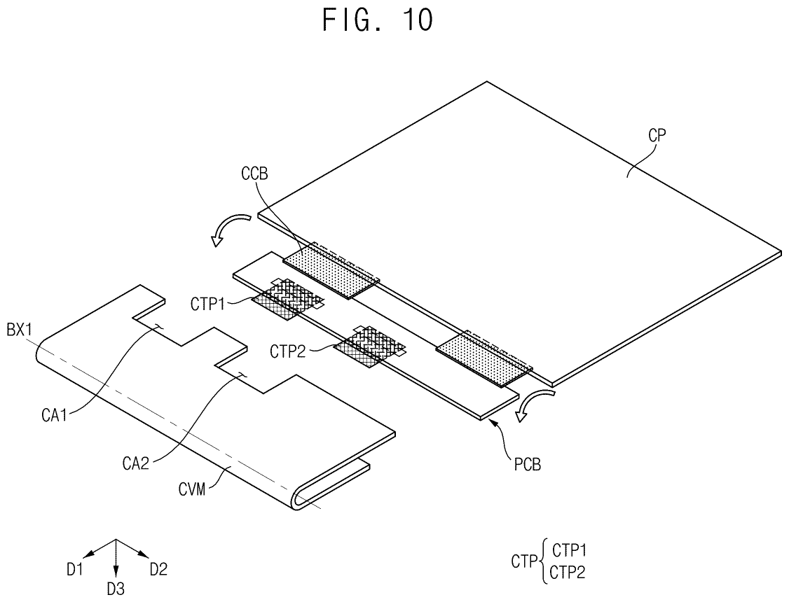

FIG. 9 is a perspective view showing an embodiment in which the cover of the display device shown in FIG. 7 is separated. FIG. 10 is a perspective view showing an embodiment in which the connection circuit board of the display device shown in FIG. 9 is in an unfolded state.

Referring to FIGS. 7, 9, and 10, the cover CVM may expose the ground portion GND of the circuit board PCB. As the first cut-out area CAL and the second cut-out area CA2 are defined in the cover CVM, at least a portion of an upper surface of the ground portion GND of the circuit board PCB may be exposed. For example, the first cut-out area CA1 may overlap with the first ground portion GND1 in a plan view, and the second cut-out area CA2 may overlap with the second ground portion GND2 in a plan view.

As shown in FIG. 9, the conductive tape CTP may be electrically connected to the ground portion GND of the circuit board PCB. For example, the first conductive tape CTP1 may be electrically connected to the first ground portion GND1, and the second conductive tape CTP2 may be electrically connected to the second ground portion GND2. In an embodiment, the conductive tape CTP may correspond one-to-one with the ground portion GND and to the cut-out area CA.

Since the conductive tape CTP is directly connected to the ground portion GND of the circuit board PCB, the likelihood of separation between the conductive tape CTP and the ground portion GND during manufacturing process or usage may be minimized. For example, by attaching the conductive tape CTP to the ground portion GND, separation is prevented or reduced, enabling reliable discharge of static electricity or similar charges generated in the display device DD.

FIG. 11 is a cross-sectional view showing an embodiment of the circuit board shown in FIG. 3.

Referring to FIGS. 3 and 11, the circuit board PCB may include the first base layer BL1, a first circuit layer CL1, a first protection layer PIL1, a second circuit layer CL2, a second protection layer PIL2, the conductive pattern PCBC, and the second base layer BL2.

The first base layer BL1 may be disposed as the bottom layer of the circuit board PCB. In an embodiment, the first base layer BL1 may be disposed as the bottommost layer of the circuit board PCB. The first base layer BL1 may include insulating materials. For example, the first base layer BL1 may include insulating materials such as polyimide (PI) or polyethylene terephthalate (PET). These materials may be used alone or in combination. However, the embodiments of the present disclosure are not necessarily limited thereto.

The first circuit layer CL1 may be disposed on the first base layer BL1. The first circuit layer CL1 may be electrically connected to the connection circuit board CCB to transmit data signals to the display panel DP. The first circuit layer CL1 may include copper (Cu) or similar materials.

The first protection layer PIL1 may be disposed on the first circuit layer CL1. The first protection layer PIL1 may include inorganic insulating materials and/or organic insulating materials.

The second circuit layer CL2 may be disposed on the first protection layer PIL1. The second circuit layer CL2 may be electrically connected to the first circuit layer CL1 through contact holes formed in the first protection layer PIL1. The second circuit layer CL2 may include a same material as the first circuit layer CL1.

The second protection layer PIL2 may be disposed on the second circuit layer CL2. The second protection layer PIL2 may include a same material as the first protection layer PIL1.

The conductive pattern PCBC may be disposed on the second protection layer PIL2. The conductive pattern PCBC may serve as a pathway for discharging static electricity or similar charges generated from the circuit board PCB. For example, the conductive pattern PCBC may be electrically connected to the cover CVM to enable discharging of static electricity through the conductive pattern PCBC.

The second base layer BL2 may be disposed on the conductive pattern PCBC. The second base layer BL2 may include a same material as the first base layer BL1. A portion of the second base layer BL2 may be removed to expose one surface of the conductive pattern PCBC, and an exposed surface of the conductive pattern PCBC may serve as the ground portion GND shown in FIG. 9.

FIG. 12 is a cross-sectional view showing an embodiment cut along the line II-II′ shown in FIG. 9. Although FIG. 12 exclusively shows the first conductive tape CTP1, the arrangement and shape of the second conductive tape CTP2 may be substantially the same as those of the first conductive tape CTP1. To the extent that an element is not described in detail with respect to this figure, it may be understood that the element is at least similar to a corresponding element that has been described elsewhere within the present disclosure.

Referring to FIGS. 9 and 12, the first conductive tape CTP1 may be electrically connected to the circuit board PCB and the cover panel CP. For example, static electricity or similar charges generated on the circuit board PCB may be transmitted to the cover panel CP through the first conductive tape CTP1. Consequently, static electricity may be discharged through the cover panel CP. The first conductive tape CTP1 may function as a bridge for transmitting static electricity from the circuit board PCB to the cover panel CP.

In an embodiment, the first conductive tape CPT1 and the cover panel CP may be attached using an adhesive. For example, the adhesive may include optically clear adhesive (OCA), optically clear resin (OCR), or pressure-sensitive adhesive (PSA). However, the embodiments of the present disclosure are not necessarily limited thereto.

FIG. 13 is a cross-sectional view showing an embodiment of the display panel shown in FIG. 3.

Referring to FIGS. 1, 3, and 13, the display panel DP may include a substrate SUB, a display element layer DEL, and an encapsulation layer ENC. The display element layer DEL may include a buffer layer BUF, a gate insulating layer GI, a transistors TR, an interlayer insulating layer ILD, a connection electrode CNE, a first via layer VIA1, a second via layer VIA2, a light-emitting diode LED, and a pixel defining layer PDL.

The transistor TR may include an active layer ACT, a gate electrode GE, a source electrode SE, and a drain electrode DE. The light-emitting diode LED may include a pixel electrode PE, a light-emitting layer EL, and a common electrode CE.

The substrate SUB may include a glass substrate, a metal substrate, or a plastic substrate. However, the embodiments of the present disclosure are not necessarily limited thereto, and the substrate SUB may be an inorganic layer, an organic layer, or a composite material layer.

The buffer layer BUF may be disposed on the substrate SUB. The buffer layer BUF may prevent impurities such as oxygen and moisture from penetrating the upper portions of the substrate SUB. The buffer layer BUF may include inorganic insulating materials.

The active layer ACT may be disposed on the buffer layer BUF. The active layer ACT may include oxide semiconductors, silicon semiconductors, or organic semiconductors. For example, the oxide semiconductors may include at least one oxide of indium (In), gallium (Ga), tin (Sn), zirconium (Zr), vanadium (V), hafnium (Hf), cadmium (Cd), germanium (Ge), chromium (Cr), titanium (Ti), and zinc (Zn). Silicon semiconductors may include amorphous silicon or polycrystalline silicon. The active layer ACT may include a source region, a drain region, and a channel region located between the source region and drain region.

The gate insulating layer GI may be disposed on the buffer layer BUF. For example, the gate insulating layer GI may cover the active layer ACT disposed on the buffer layer BUF. The gate insulating layer GI may include inorganic insulating materials. In an embodiment, the gate insulating layer GI may be disposed across the display area DA and the peripheral area SA. In an embodiment, the gate insulating layer GI may be disposed exclusively under the gate electrode GE.

The gate electrode GE may be disposed on the gate insulating layer GI. The gate electrode GE may at least partially overlap the channel region of the active layer ACT. The gate electrode GE may include conductive materials such as metal, alloy, conductive metal nitride, conductive metal oxide, or transparent conductive materials. Examples of such conductive materials include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), aluminum alloys, silver alloys, copper alloys, molybdenum alloys, aluminum nitride (AlN), tungsten nitride (WN), titanium nitride (TiN), chromium nitride (CrN), tantalum nitride (TaN), strontium ruthenium oxide (SrRuO₃), zinc oxide (ZnO), indium tin oxide (ITO), tin oxide (SnO₂), indium oxide (In₂O₃), gallium oxide (Ga₂O₃), or indium zinc oxide (IZO). These materials may be used alone or in combination.

The interlayer insulating layer ILD may be disposed on the gate electrode GE. For example, the interlayer insulating layer ILD may be disposed on the gate insulating layer GI, covering the gate electrode GE. The interlayer insulating layer ILD may include inorganic insulating materials. In an embodiment, the interlayer insulating layer ILD may be disposed across the display area DA and the peripheral area SA.

The source electrode SE and the drain electrode DE may be disposed on the interlayer insulating layer ILD. Each of the source electrode SE and the drain electrode DE may be connected to the active layer ACT. For example, the source electrode SE may contact the source region of the active layer ACT, and the drain electrode DE may contact the drain region of the active layer ACT. Each of the source electrode SE and the drain electrode DE may include conductive materials. The active layer ACT, the gate electrode GE, the source electrode SE, and the drain electrode DE may form the transistor TR.

A first via layer VIA1 may be disposed on the source electrode SE and the drain electrode DE. For example, the first via layer VIA1 may be disposed on the interlayer insulating layer ILD, covering the source electrode SE and the drain electrode DE. The first via layer VIA1 may include organic insulating materials. In an embodiment, the first via layer VIA1 may be formed exclusively in a portion of the peripheral area SA adjacent to the display area DA.

The connection electrode CNE may be disposed on the first via layer VIA1. The connection electrode CNE may transmit signals from the transistor TR to the light-emitting diode LED. The connection electrode CNE may include metals, alloys, metal nitrides, conductive metal oxides, or transparent conductive materials. These materials may be used alone or in combination. However, the embodiments of the present disclosure are not necessarily limited thereto.

The second via layer VIA2 may be disposed on the connection electrode CNE. For example, the second via layer VIA2 may be disposed on the first via layer VIA1, covering the connection electrode CNE. The second via layer VIA2 may include substantially a same material as the first via layer VIA1.

The pixel electrode PE may be disposed on the second via layer VIA2. The pixel electrode PE may include conductive materials and may be connected to the drain electrode DE through the connection electrode CNE. Accordingly, the pixel electrode PE may be electrically connected to the transistor TR.

The pixel defining layer PDL may be disposed on the pixel electrode PE. For example, the pixel defining layer PDL may expose at least a portion of the pixel electrode PE. The pixel defining layer PDL may include inorganic insulating materials or organic insulating materials.

The light-emitting layer EL may be disposed on the pixel electrode PE. In an embodiment, the light-emitting layer EL may be disposed within an opening defined by the pixel defining layer PDL. For example, the light-emitting layer EL may be surrounded by the pixel defining layer PDL. In an embodiment, the light-emitting layer EL may also be disposed on the pixel defining layer PDL. The light-emitting layer EL may include at least one of the organic light-emitting materials. In an embodiment, the light-emitting layer EL may include the organic light-emitting materials or quantum dots. However, the embodiments of the present disclosure are not necessarily limited thereto.

A common electrode CE may be disposed on the light-emitting layer EL. The common electrode CE may also be disposed on the pixel defining layer PDL. For example, the common electrode CE may be continuously disposed on the light-emitting layer EL and the pixel defining layer PDL. The common electrode CE may include conductive materials. The light-emitting layer EL may emit light based on a voltage difference between the pixel electrode PE and the common electrode CE.

The encapsulation layer ENC may be disposed on the common electrode CE. The encapsulation layer ENC may include at least one inorganic encapsulation layer and at least one organic encapsulation layer. In an embodiment, the inorganic encapsulation layer and the organic encapsulation layer may be alternately disposed. For example, the organic encapsulation layer may include polymerized curing elements such as polyacrylate, epoxy resin, or silicone resin. In contrast, the inorganic thin film may include materials such as silicon oxide, silicon nitride, silicon carbide, aluminum oxide, tantalum oxide, hafnium oxide, zirconium oxide, or titanium oxide.

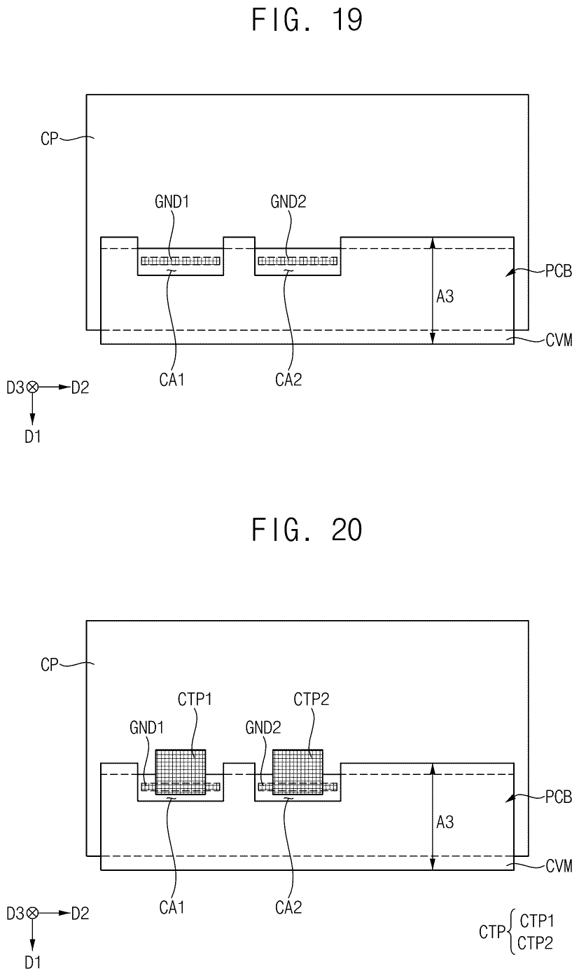

FIGS. 14, 15, 16, 17, 18, 19, and 20 are plan views showing a manufacturing method of the display device shown in FIG. 2. For example, FIGS. 14 through 18 show the upper surface of the display panel DP, and FIGS. 19 and 20 show a rear surface of the display panel DP.

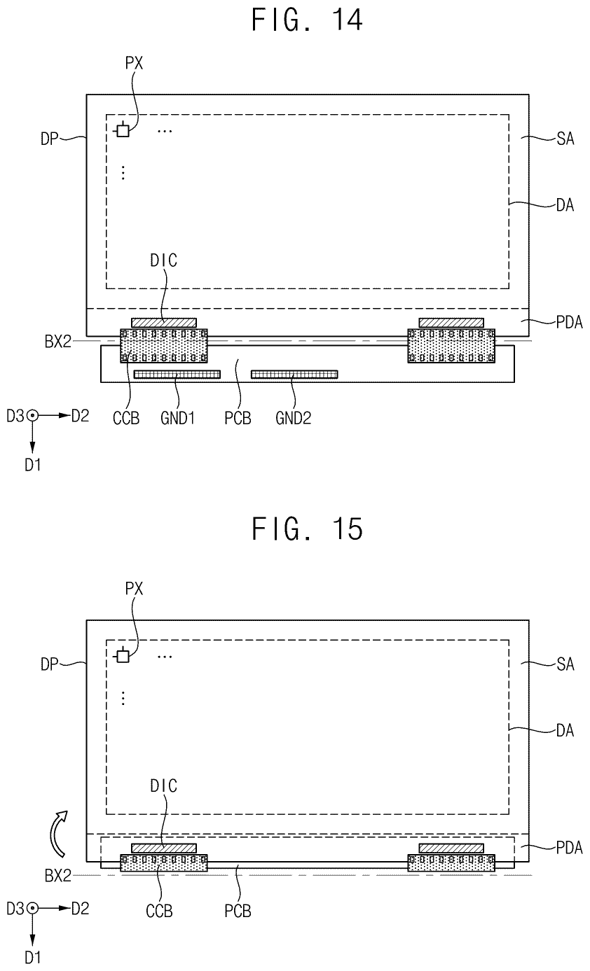

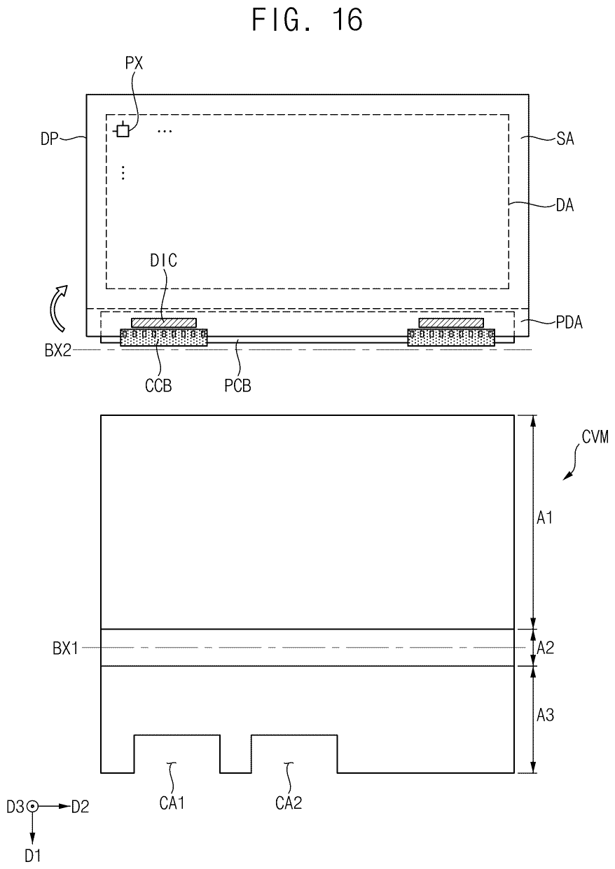

Referring to FIGS. 14 and 15, the connection circuit board CCB may be attached to the pad area PDA of the display panel DP. In an embodiment, the connection circuit board CCB may be bent around the second bending axis BX2. For example, the circuit board PCB connected to the connection circuit board CCB may be disposed below the substrate SUB.

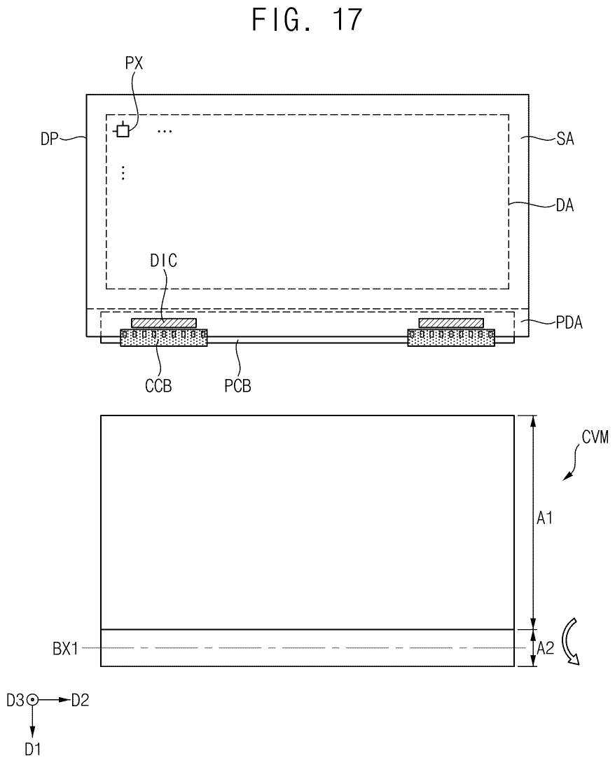

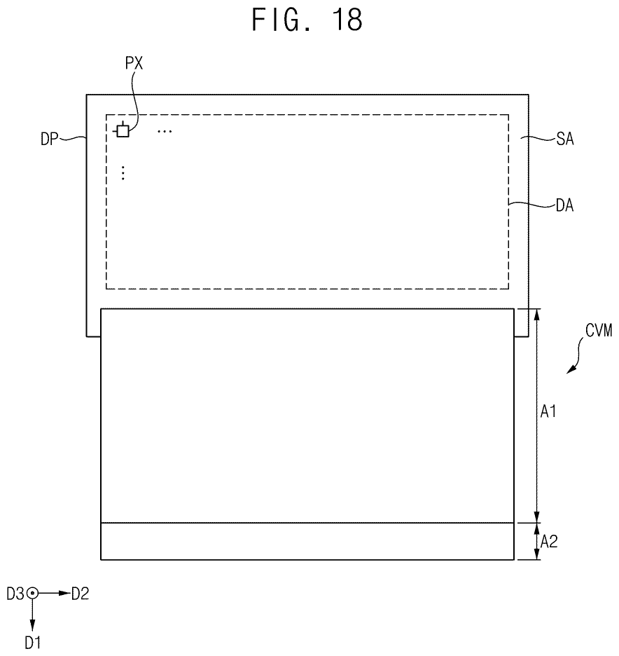

Referring further to FIGS. 16 and 17, the cover CVM may be bent around the first bending axis BX1. The first bending axis BX1 may be an arbitrary axis located in the second area A2. By bending the cover CVM along the first bending axis BX1, the cover CVM may cover at least portions of both upper and lower surfaces of the display panel DP.

Referring further to FIGS. 17 and 18, the cover CVM bent along the first bending axis BX1 may be attached to one end of the pad area PDA of the display panel DP. By attaching the cover CVM to the pad area PDA of the display panel DP, the cover CVM may physically protect the driver chip DIC and the circuit board PCB.

Referring further to FIG. 19, the first cut-out area CAL and the second cut-out area CA2 of the cover CVM may expose the first ground portion GND1 and the second ground portion GND2, respectively. For example, even when the cover CVM is attached to the pad area PDA, the first cut-out area CAL and the second cut-out area CA2 may expose the first ground portion GND1 and the second ground portion GND2 of the circuit board PCB.

Referring further to FIG. 20, the first conductive tape CTP1 may be attached to the first cut-out area CA1, and the second conductive tape CTP2 may be attached to the second cut-out area CA2. In an embodiment, the first conductive tape CTP1 may be attached to overlap the first cut-out area CA1, and the second conductive tape CTP2 may be attached to overlap the second cut-out area CA2. For example, the first conductive tape CTP1 may be electrically connected to the first ground portion GND1 and the cover panel CP. The second conductive tape CTP2 may be electrically connected to the second ground portion GND2 and the cover panel CP. For example, as shown in FIG. 12, each of the first conductive tape CTP1 and the second conductive tape CTP2 may electrically connect the circuit board PCB and the cover panel CP.

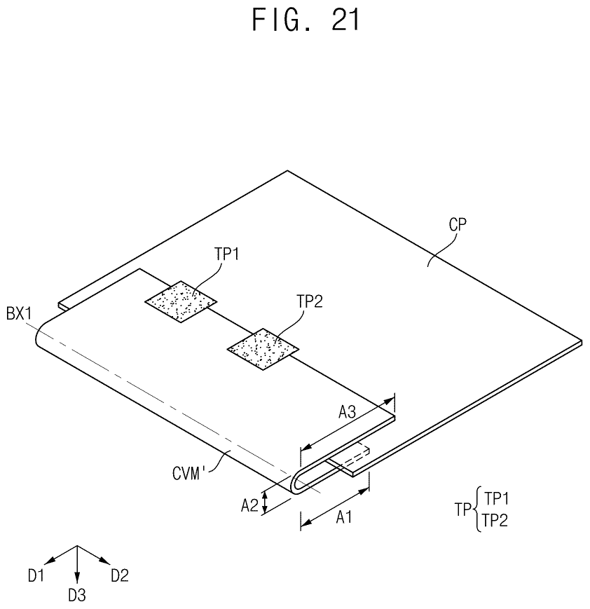

FIG. 21 is a perspective view showing an embodiment of a rear side of the display device shown in FIG. 2.

Referring to FIGS. 2 and 21, a tape TP may be attached to one side of the cover CVM′. In an embodiment, the tape TP may be an adhesive tape. The tape TP may securely attach the circuit board PCB and the cover CVM′ to prevent them from detaching. For example, the tape TP may adhere to a surface of the cover CVM′ and the cover panel CP, pressing the cover CVM′. In an embodiment, the tape TP may adhere to an upper surface of the cover CVM′ and the cover panel CP. The tape TP may include insulating materials.

For example, the tape TP may include a first tape TP1 and a second tape TP2. The first tape TP1 and the second tape TP2 may be spaced apart in the second direction D2. However, the embodiments of the present disclosure are not necessarily limited thereto. The tape TP may include one or three or more tapes.

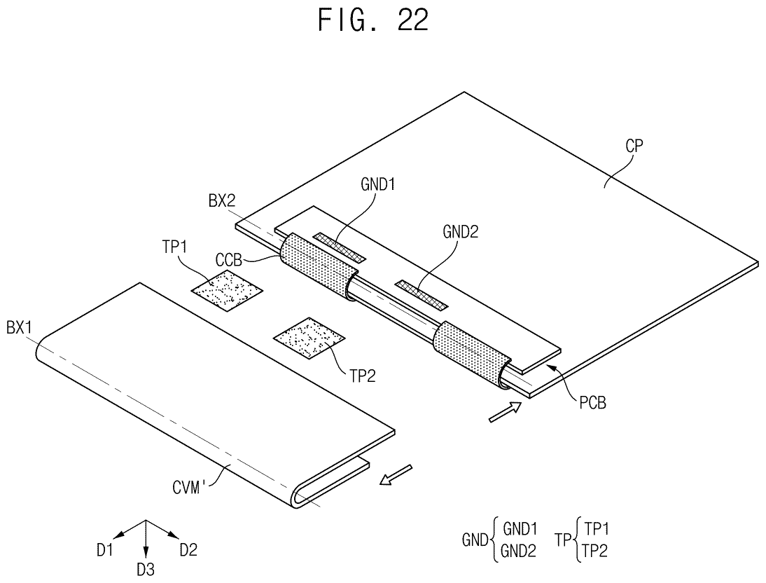

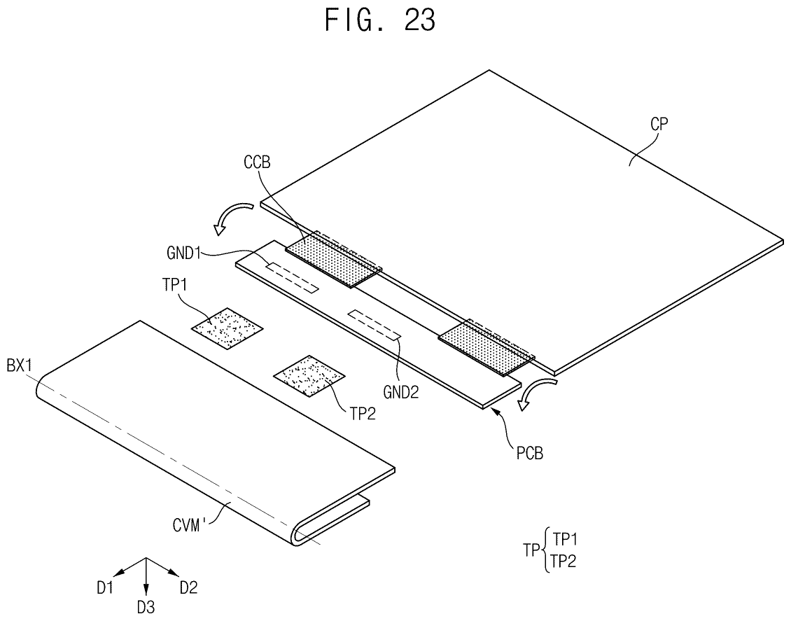

FIG. 22 is a perspective view showing an embodiment in which the cover of the display device shown in FIG. 21 is separated. FIG. 23 is a perspective view showing an embodiment in which the connection circuit board of the display device shown in FIG. 22 is in an unfolded state.

Referring to FIGS. 21, 22, and 23, the first tape TP1 may overlap at least partially with the first ground portion GND1 in a plan view, and the second tape TP2 may overlap at least partially with the second ground portion GND2 in a plan view. For example, the tape TP may correspond one-to-one with the ground portion GND.

While FIG. 9 shows that the conductive tape CTP may be electrically connected to the ground portion GND, FIG. 21 illustrates that the cover CVM′ may be electrically connected to the ground portion GND of the circuit board PCB. Accordingly, the cover CVM′ may connect to the circuit board PCB, allowing static electricity or similar charges generated on the circuit board PCB to be discharged through the cover CVM′. For example, the tape TP may ensure better attachment between the ground portion GND of the circuit board PCB and the cover CVM′, ensuring less likelihood of detachment.

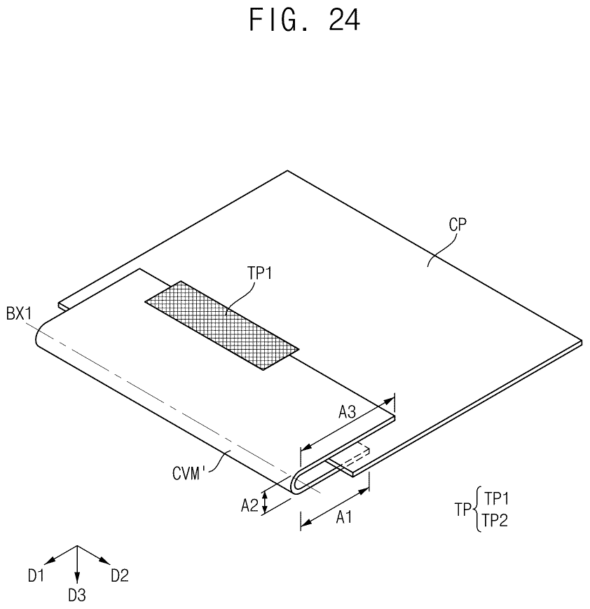

FIG. 24 is a perspective view showing an embodiment of a rear side of the display device shown in FIG. 2.

Referring to FIGS. 22 and 24, the first tape TP1 may have a longitudinal axis extending along the second direction D2. For example, the first tape TP1 may overlap in a plan view with both the first ground portion GND1 and the second ground portion GND2, independently. In an embodiment, the cover CVM′ and the ground portion GND may adhere securely without separation.

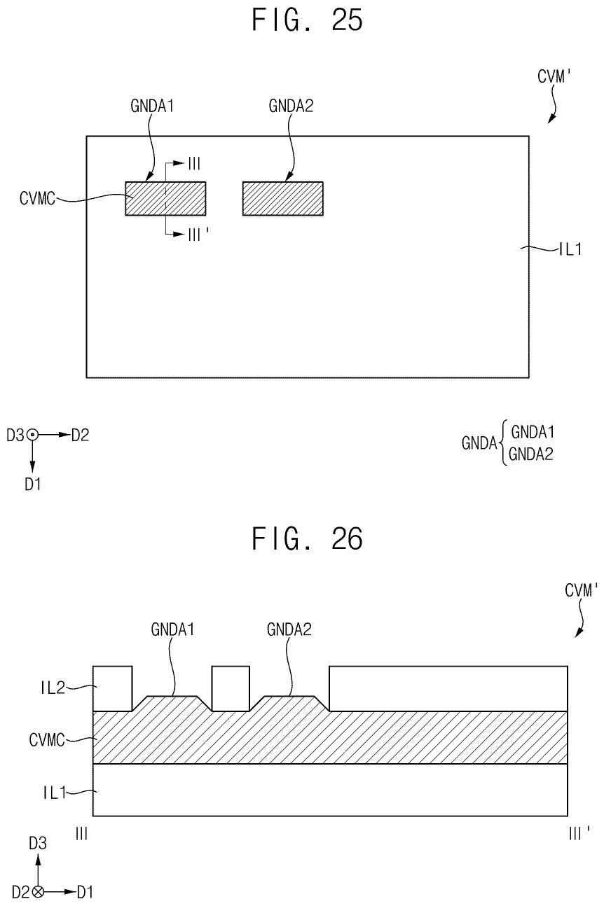

FIG. 25 is a plan view showing an embodiment of the ground portion of the cover shown in FIG. 22. FIG. 26 is a cross-sectional view showing an embodiment cut along the line III-III′ of FIG. 25.

Referring to FIGS. 22 and 25, a ground area GNDA may be defined in the cover CVM′. The ground area GNDA may expose one surface of the conductive layer CVMC by removing a portion of the first insulating layer IL1.

The ground area GNDA may include a first ground area GNDA1 and a second ground area GNDA2. For example, the first ground area GNDA1 and the second ground area GNDA2 may be spaced apart along the second direction D2. While FIG. 25 shows the ground area GNDA having a rectangular shape in a plan view, the embodiments of the present disclosure are not necessarily limited thereto.

Referring further to FIGS. 22, 25, and 26, the conductive layer CVMC exposed through the first ground area GNDA1 may be electrically connected to the first ground portion GND1. In an embodiment, the conductive layer CVMC exposed through the second ground area GNDA2 may be electrically connected to the second ground portion GND2.

As shown in FIG. 26, the first ground area GNDA1 and the second ground area GNDA2 may have a depth corresponding to a thickness of the first insulating layer IL1. The conductive layer CVMC and the ground portion GND may be separated during the manufacturing process due to the difference in depth. In an embodiment, the tape TP may attach the conductive layer CVMC and the ground portion GND, ensuring that the conductive layer CVMC and the ground portion GND are not separated.

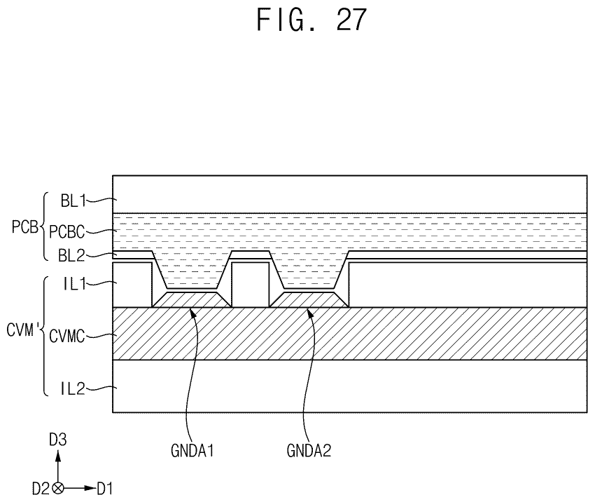

FIG. 27 is a cross-sectional view showing an embodiment in which the cover shown in FIG. 26 contacts the circuit board PCB.

Referring to FIGS. 21, 22, 26, and 27, the cover CVM′ may contact the circuit board PCB. For example, the cover CVM′ may be electrically connected to the circuit board PCB. The tape TP may prevent or reduce the separation between the cover CVM′ and the circuit board PCB.

In an embodiment, as shown in FIG. 27, the conductive pattern PCBC of the circuit board PCB may contact the cover CVM′ due to a portion of the second base layer BL2 being removed. For example, an exposed portion of the conductive pattern PCBC may serve as the ground portion GND in FIG. 22. Static electricity or similar charges generated on the circuit board PCB may be reliably discharged through the cover CVM′.

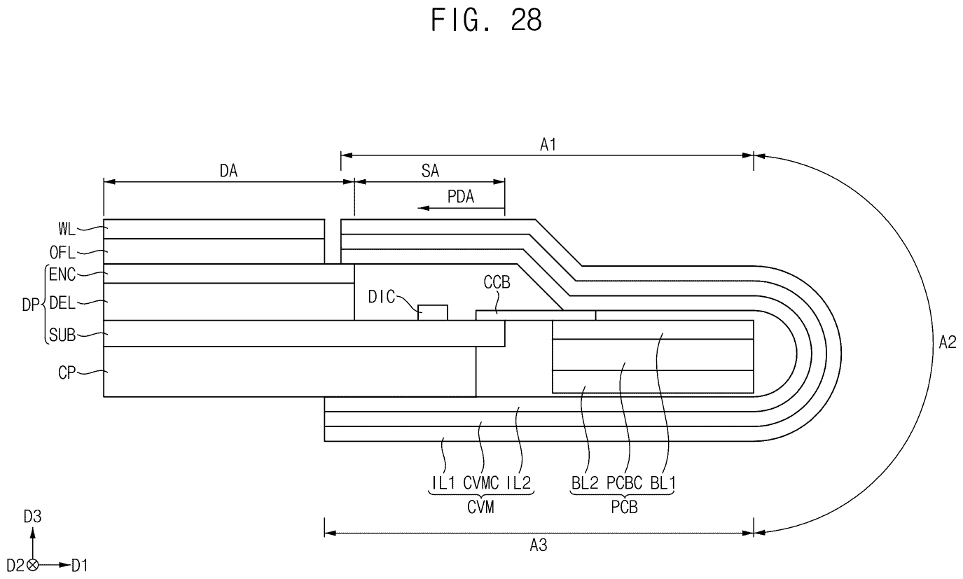

FIG. 28 is a cross-sectional view showing an embodiment cut along the line I-I′ of the display device shown in FIG. 2.

Referring to FIGS. 2 and 28, the connection circuit board CCB may extend in the first direction D1 without being bent around the bending axis. Accordingly, the circuit board PCB attached to the connection circuit board CCB may be spaced apart from the substrate SUB in a plan view.

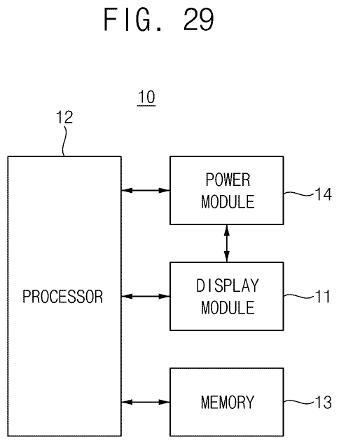

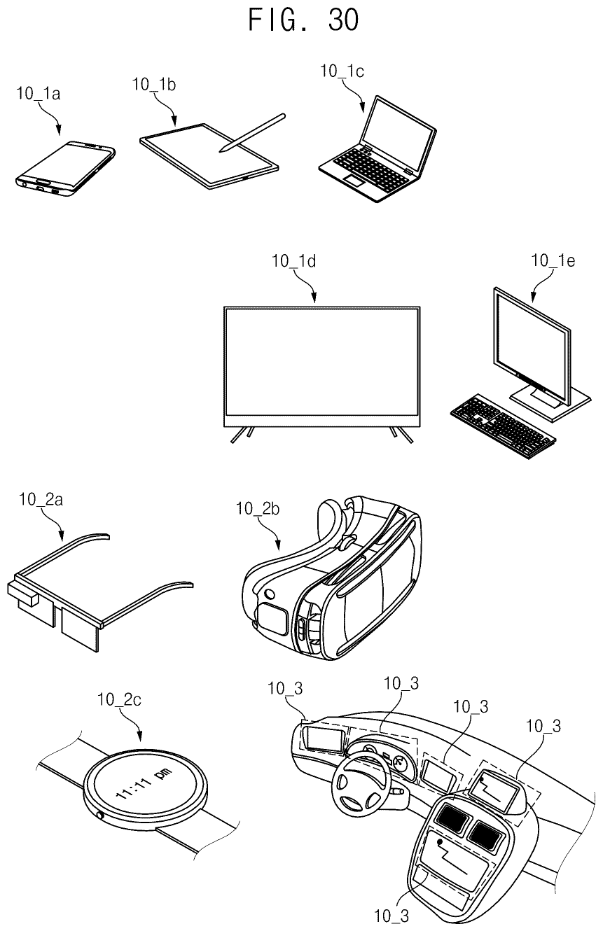

FIG. 29 is a block diagram showing an electronic device according to an embodiment of the present disclosure.

Referring to FIGS. 1 and 29, the display device DD, according to the embodiments, may be applied to various electronic devices 10. The electronic device 10, according to an embodiment, may include the above-described display device DD and additional modules or devices with other functionalities.

The electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data or information required for the operation of the processor 12 or the display module 11. When the processor 12 executes an application stored in the memory 13, video data signals and/or input control signals may be transmitted to the display module 11. The display module 11 may process the received signals and output visual information through a display screen.

The power module 14 may include power supply modules such as power adapters or battery devices and may convert the power supplied by the power supply module. For example, the power module 14 may include a power conversion module for generating power required for the operation of the electronic device 10.

At least one of the above-described components of the electronic device 10 may be included within the display device according to the embodiments. In an embodiment, some components functionally included in a single module may be partially included in the display device and partially provided separately. For example, the display device DD may include the display module 11, while the processor 12, the memory 13, and the power module 14 may be provided as part of another device within the electronic device 10 rather than the display device DD.

FIG. 30 is a schematic diagram showing various embodiments of the electronic device shown in FIG. 29.

Referring to FIGS. 29 and 30, various electronic devices 10 incorporating the display device DD according to the embodiments may include image display devices such as smartphones 10_1a, tablet computers 10_1b, laptop computers 10_1c, TVs 10_1d, or computer monitors 10_1e. In some embodiments, wearable electronic devices such as smart glasses 10_2a, head-mounted displays 10_2b, or smartwatches 10_2c that include display modules may also be included. In some embodiments, automotive electronic devices 10_3, such as center information displays (CID), dashboard displays, or room mirror displays, incorporating display modules, may also be included.

However, these examples are illustrative, and the electronic device 10 according to the embodiments of the present disclosure is not necessarily limited thereto. For example, the electronic device 10 may be implemented as a mobile phone, a videophone, a smart pad, a smartwatch, a tablet computer, a vehicle display, a computer monitor, a laptop computer, or a head-mounted display device. In an embodiment, the electronic device 10 may be a television. In an embodiment, the electronic device 10 may be a vehicle.

Those skilled in the art will recognize that the present disclosure can be practiced in other specific ways without departing from its technical spirit or essential characteristics. The described embodiments should be regarded as illustrative rather than being restrictive in all aspects. Although embodiments of the present disclosure have been described with reference to the accompanying drawings, the disclosure is not necessarily limited to these embodiments and may be implemented in various forms.

What is claimed is:

1. A display device, comprising:
a display panel including:
a display area including a plurality of pixels; and
a peripheral area proximate to the display area, the peripheral area including a pad area spaced apart from a side of the display area in a first direction;
a printed circuit board electrically connected to the display panel, the printed circuit board including at least one ground portion;
a cover covering the printed circuit board, the cover including at least one cut-out area exposing the at least one ground portion; and
a conductive tape disposed in the at least one cut-out area, wherein the conductive tape is electrically connected to the at least one ground portion of the printed circuit board.

2. The display device of claim 1, wherein the cover includes:
a first insulating layer;
a conductive layer disposed on the first insulating layer; and
a second insulating layer disposed on the conductive layer.

3. The display device of claim 2, wherein the conductive tape includes:
a discharge layer including a conductive material; and
a cover layer disposed on the discharge layer, the cover layer including an insulating material.

4. The display device of claim 3, wherein:
the discharge layer includes a same material as the conductive layer of the cover, the cover layer includes a same material as the first insulating layer, and
the cover layer includes a same material as the second insulating layer of the cover.

5. The display device of claim 4, wherein the discharge layer and the conductive layer both include aluminum.

6. The display device of claim 3, further comprising:
a cover panel disposed under the display panel, the cover panel including a conductive material.

7. The display device of claim 6, wherein the discharge layer of the conductive tape is electrically connected to the cover panel and the at least one ground portion.

8. The display device of claim 1, the conductive tape is spaced apart from the cover.

9. The display device of claim 1, wherein the at least one cut-out area of the cover corresponds one-to-one with the at least one ground portion.

10. The display device of claim 1, wherein the conductive tape corresponds one-to-one with the at least one ground portion and the at least one cut-out area.

11. The display device of claim 4, further comprising:
a driver chip disposed on the pad area of the display panel, the driver chip configured to provide driving signals to the plurality of pixels.

12. The display device of claim 1, further comprising:
a connection circuit board disposed on the pad area of the display panel,
wherein the connection circuit board is connected to the display panel and the printed circuit board.

13. The display device of claim 12, wherein the connection circuit board is bent around a bending axis extending parallel to a second direction, the second direction intersecting the first direction.

14. The display device of claim 1, wherein:
the cover includes an insulating material, and the cover is single-layered.

15. A display device, comprising:
a display panel including:
a display area including a plurality of pixels; and
a peripheral area including a pad area proximate to the display area, wherein the pad area is spaced apart from a side of the display area in a first direction;
a cover panel disposed under the display panel, the cover panel including a conductive material;
a printed circuit board electrically connected to the display panel, the printed circuit board including at least one ground portion;
a cover covering the printed circuit board, the cover electrically connected to the at least one ground portion; and
an adhesive tape attached to the cover and to the cover panel, wherein at least a portion of the adhesive tape overlaps the at least one ground portion of the printed circuit board.

16. The display device of claim 15, wherein the cover includes:
a first insulating layer;
a conductive layer disposed on the first insulating layer; and
a second insulating layer disposed on the conductive layer.

17. The display device of claim 16, wherein:
a ground area is defined in the cover by removing a portion of the first insulating layer to expose one surface of the conductive layer.

18. The display device of claim 17, wherein the ground area of the cover corresponds one-to-one with the at least one ground portion, and
wherein the adhesive tape corresponds one-to-one with the at least one ground portion and to the ground area.

19. The display device of claim 15, further comprising:
a connection circuit board disposed on the peripheral area of the display panel, wherein the connection circuit board is bent around a bending axis extending parallel to a second direction, and wherein the second direction intersects the first direction.

20. An electronic device, comprising:
a display device; and
a processor configured to drive the display device,
wherein the display device comprises:
a display panel including:
a display area including a plurality of pixels; and
a peripheral area proximate to the display area, the peripheral area including a pad area spaced apart from a side of the display area in a first direction;
a printed circuit board electrically connected to the display panel, the printed circuit board including at least one ground portion;
a cover covering the printed circuit board, the cover including at least one cut-out area exposing the at least one ground portion; and
a conductive tape disposed in the at least one cut-out area, wherein the conductive tape is electrically connected to the at least one ground portion of the printed circuit board.
